(19) United States
(12) Patent Application Publication
(10) Pub. No.: US 2006/0084206 A1
(43) Pub. Date: Apr. 20, 2006

(54) Thin-film pattern forming method, semiconductor device, electro-optic device, and electronic apparatus

(75) Inventors: Katsuyuki Moriya, Toyoshina (JP); Toshimitsu Hirai, Chino (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/244,805

(22) Filed: Oct. 6, 2005

(30) Foreign Application Priority Data
Oct. 15, 2004 (JP) 2004-301052

(51) Int. Cl. H01L 21/84

(52) U.S. Cl. 438/149; 257/66; 438/674

(57) ABSTRACT

A thin-film pattern forming method that deposits a plurality of thin films on a substrate to form a thin-film pattern, includes: forming a second thin film on the substrate, the second thin film having an affinity for a functional liquid containing a thin-film material that makes up a first thin film; providing lyophobic treatment that makes a surface of the second thin film repellent to the functional liquid; forming a concave portion that defines a pattern shape of the first thin film by removing part of the second thin film; discharging the functional liquid to the concave portion; and forming the first thin film by drying the functional liquid discharged to the concave portion.

### BACKGROUND

1. Technical Field

The present invention relates to a thin-film pattern forming method and a semiconductor device, an electro-optic device and an electronic apparatus that are manufactured by using the thin-film pattern forming method.

2. Related Art

A related art semiconductor device is provided by depositing a circuit wiring on which a conductive thin film (hereinafter referred to as a wiring film) is placed, a thin film such as an insulating film to cover the circuit wiring, and a semiconductor thin film on a substrate. In order to efficiently form a thin film, the so-called inkjet method is used. The method is to form a thin film by discharging droplets of a functional liquid containing a thin-film material, etc. as a solute from a droplet discharge head and drying the functional liquid that has been landed to remove a solvent. JP-A-11-274671 is an example of related art. In the inkjet method, a concave portion having the same planar shape as a thin-film pattern is provided on the substrate by placing a bank so as to surround a thin-film forming area on the substrate. The functional liquid is discharged to this concave portion. By drying the functional liquid that has been landed in the concave portion, a thin film is formed in a pattern defined by the thin film's function.

Although droplets of the functional liquid that have been discharged to be landed in the concave portion are preferably placed in the concave portion, part of them may be placed on the upper surface of the bank. In order to make the functional liquid not to stay on the upper surface of the bank and to flow into the concave portion, it is preferable that the upper surface of the bank is repellent to the functional liquid (lyophobic) while the bottom and side of the concave portion have an affinity for the functional liquid (lyophilic). To make the concave portion lyophilic, a method to provide surface treatment with a lyophilic treatment agent that gives lyophilicity to the concave portion (e.g. JP-A-9-203803) and a method to control lyophilicity by applying an energy line after forming the concave portion (e.g. JP-A-9-230129) have been proposed, for example.

When using the method disclosed in JP-A-9-203803, the bottom of the concave portion where the lyophilic treatment agent is deposited successfully becomes lyophilic, while the side of the concave portion where the lyophilic treatment agent is difficult to stay is hard to become lyophilic. Accordingly, the bank whose upper surface is made lyophobic has a side, which is also a side of the concave portion, that is lyophobic in the same manner as the upper surface of the bank. When using the method disclosed in JP-A-9-230129, it is difficult to selectively treat the concave portion, and the upper surface of the bank, which is preferably lyophobic, becomes lyophilic. If the upper surface of the bank, which has been made lyophilic, is subjected to lyophobic treatment, the side of the concave portion, which is also the side of the bank, becomes lyophobic as well.

FIG. 18 is a sectional view schematically showing a functional liquid in a concave portion formed by a bank on a substrate when providing a wiring film by depositing the functional liquid to the concave portion. Referring to FIGS. 18A and 18B, a functional liquid is discharged to a concave portion formed by a bank 504. A bank upper surface 507 is repellent to this functional liquid 511, while the bottom and a side 506 of the concave portion have an affinity for the functional liquid 511. Referring to FIGS. 18C and 18D, a functional liquid is discharged to a concave portion formed by a bank 508. The bank upper surface 507 and a side 509 are repellent to this functional liquid 516, while the bottom of the concave portion has an affinity for the functional liquid 516.

On a semiconductor layer 502, a bonding layers 503 made of an n+ a-Si layer, for example, is deposited in order to provide ohmic bonding. When the bottom and the side of the concave portion have an affinity for the functional liquid, as shown in FIG. 18A, the functional liquid 511 is repelled by the bank upper surface 507 and deposited in the concave portion, which is a thin-film forming area, whose bottom and side are lyophilic. The functional liquid 511 beyond the capacity of the concave portion is repelled by the bank upper surface 507 and does not flow to the bank upper surface 507. Accordingly, the surface of the functional liquid 511 deposited in the concave portion is projecting. Drying the functional liquid 511 provides an electrode 512 having a shape that sufficiently covers the bonding layer 503 and a wiring film 514 having a sufficient sectional area spreading to the corners of the concave portion, as shown in FIG. 18B.

Meanwhile, when the side of the concave portion is repellent to the functional liquid, as shown in FIG. 18C, the functional liquid 516 is repelled by the bank upper surface 507 and the side 509 and piled on the bottom of the concave portion, which is a thin-film forming area. Accordingly, the cross section of the concave portion has a gap that is not filled with the functional liquid. In this case, drying the functional liquid 516 makes part of the concave portion near the side thin, and thereby providing an electrode 517 having a shape that fails to sufficiently cover the bonding layer 503 and a wiring film 518 without a sufficient sectional area that is deposited unevenly on the bottom of the concave portion, as shown in FIG. 18D. Moreover, when the width of the concave portion is even smaller, a thin film may not be formed at all as the functional liquid cannot enter the concave portion. This is because adjacent and opposing sides repel the functional liquid, thereby preventing the functional liquid from flowing into the concave portion. It is nearly impossible to adjust the sectional shape of a thin film formed in only part of the concave portion so that the film can have a required shape in consideration of a non-filled area.

This way, the side of the concave portion and the upper surface of the bank both of which are lyophobic involve the problem in that a thin film formed in the concave portion fails to have a necessary film thickness and sectional shape. Furthermore, it is difficult to form a minute thin film.

### SUMMARY

An advantage of the invention is to provide a thin-film pattern forming method, that is capable of forming a thin film having a sufficient sectional area and necessary sectional shape for a thin film formed in a concave portion to provide the film's function by filling the whole sectional area of the concave portion that is a thin-film forming area with a functional liquid, and to provide a semiconductor device, an electro-optic device, and an electronic apparatus.

A thin-film pattern forming method according to an aspect of the invention is to deposit a plurality of thin films on a substrate to form a thin-film pattern. The thin-film pattern forming method includes: forming a second thin film on the substrate, the second thin film having an affinity for a functional liquid containing a thin-film material that makes up a first thin film; providing lyophobic treatment that makes a surface of the second thin film repellent to the functional liquid; forming a concave portion that defines a pattern shape of the first thin film by removing part of the second thin film; discharging the functional liquid to the concave portion; and forming the first thin film by drying the functional liquid discharged to the concave portion.

According to this method, by providing lyophobic treatment to make the surface of the second thin film repellent to the functional liquid containing a thin-film material that makes up the first thin film, the upper surface of the second thin film becomes lyophobic. Meanwhile, by forming the second thin film with a material having an affinity for the functional liquid containing a thin-film material that makes up the first thin film and forming the concave portion after the lyophobic treatment to the surface of the second thin film, the side of the concave portion becomes lyophilic. Since the upper surface of the second thin film making up the concave portion is lyophobic while the side of the concave portion is lyophilic, part of the functional liquid that deviates from the concave portion and is placed on the upper surface of the second thin film is repelled by upper surface of the second thin film, which is lyophobic, and thus flows into the concave portion. The functional liquid in the concave portion spreads to the side of the concave portion, which is lyophilic, and thereby filling the whole area of the concave portion. Accordingly, by forming the concave portion having a sectional shape corresponding to a necessary film thickness and sectional area for a thin film and drying the functional liquid filling the concave portion, a thin film with a necessary film thickness and sectional area can be provided. In other words, a thin film having a sufficient film thickness and sectional area to provide its function can be formed.

Moreover, even if the width of the concave portion is small, flowing of the functional liquid into the concave portion is unlikely. This problem is likely to happen with a conventional concave portion whose side is lyophobic, since adjacent and opposing sides repel the functional liquid. Therefore, it is possible to fill the concave portion whose width is small with the functional liquid. Thus it is easy to form a thin-film pattern with a more minute planar shape.

Here, in forming the second thin film on the substrate, a material whose contact angle with respect to the functional liquid is 20 degrees or less is preferably used as a material for forming the second thin film.

With the material whose contact angle with respect to the functional liquid containing a thin-film material that makes up the second thin film is 20 degrees or less used for forming the second thin film, it is possible to make a side of the concave portion to which the material for forming the second thin film is exposed have an affinity for the functional liquid.

Here, in providing lyophobic treatment, a contact angle of the surface of the second thin film with respect to the functional liquid is preferably 90 degrees or more.

With the upper surface of the second thin film whose contact angle with respect to the functional liquid containing a thin-film material that makes up the first thin film is 90 degrees or more, it is possible to make the upper surface of the second thin film repellent to a sufficiently degree for repelling the functional liquid placed on the upper surface of the second thin film so that the liquid will flow into the concave portion.

Here, the first thin film is preferably at least one of a source electrode and a source wiring of a semiconductor device.

This method can form a film of the source electrode provided on a semiconductor layer to an even thickness to the side of the concave portion of the second thin film. As for the source electrode and a drain electrode of a thin-film transistor (TFT) that is a semiconductor device, a contact portion that makes contact with a semiconductor layer and transfers electrons is provided on the semiconductor layer. The source electrode and the drain electrode are separated by a bank that is formed of the second thin film provided on the semiconductor layer. Thus they are not conductive directly to each other and bonded with the semiconductor layer therebetween. Since the source electrode and the drain electrode are electron paths, their cross sections perpendicular to the flow of electrons preferably have a sufficient area for flowing a necessary amount of electrons. In particular, an area near the contact portion that makes contact with the semiconductor layer and transfers electrons preferably have a sufficient area for flowing a necessary amount of electrons. By providing the film to an even thickness to the side of the concave portion of the second thin film, it is possible to make the shape of the source electrode near the contact portion have such a sectional area that can easily flow a necessary amount of electrons.

With this method, the functional liquid in the concave portion for forming the source wiring spreads to the side of the concave portion, which is lyophilic, and thereby filling the whole area of the concave portion. By drying the functional liquid filling the concave portion, it is possible to provide a source wiring film having a sufficient sectional area to an even film thickness. Furthermore, it is possible to fill the concave portion whose width is small with the functional liquid. Thus it is easy to form a more minute source wiring.

Here, the first thin film is preferably a drain electrode of a TFT.

This method can form a film of the drain electrode provided on a semiconductor layer to an even thickness to the side of the concave portion of the second thin film. As for the drain electrode and a source electrode of a TFT that is a semiconductor device, a contact portion that makes contact with a semiconductor layer and transfers electrons is provided on the semiconductor layer. The drain electrode and the source electrode are separated by a bank that is formed of the second thin film provided on the semiconductor layer. Thus they are not conductive directly to each other and bonded with the semiconductor layer therebetween. Since the drain electrode and the source electrode are electron paths, their cross sections perpendicular to the flow of electrons have preferably a sufficient area for flowing a necessary amount of electrons. In particular, an area near the contact portion that makes contact with the semiconductor layer and transfers electrons preferably have a sufficient area for flowing a necessary amount of electrons. By providing the film to an even thickness to the side of the concave portion of the second thin film, it is possible to make the shape of the drain electrode near the contact portion have such a sectional area that can easily flow a necessary amount of electrons.

Here, the first thin film is preferably at least one of a gate wiring and a gate electrode of a semiconductor device.

With this method, the functional liquid in the concave portion for forming the gate wiring and the gate electrode spreads to the side of the concave portion, which is lyophilic, and thereby filling the whole area of the concave portion. By drying the functional liquid filling the concave portion, it is possible to provide a gate wiring film and a gate electrode film having sufficient sectional areas to an even film thickness. Furthermore, it is possible to fill the concave portion whose width is small with the functional liquid. Thus it is easy to form a more minute gate wiring and gate electrode.

A semiconductor device according to another aspect of the invention includes the first thin film formed by the above-described thin-film pattern forming method.

In the semiconductor device with this structure, the upper surface of the second thin film making up the concave portion that is a thin-film forming area is made lyophobic while the side of the concave portion of the second thin film is made lyophilic. Since the device is formed by the thin-film pattern forming method that is capable of forming a thin film having a sufficient sectional area and a necessary sectional shape in a concave portion, it has a sufficient film thickness and sectional area for providing the thin film's function. Therefore, a semiconductor device that offers high performance with a thin film that is capable of providing its function can be provided.

An electro-optic device according to yet another aspect of the invention includes the above-described semiconductor device.

With this structure, since the semiconductor device offers high performance with a thin film that is capable of providing its function, an electro-optic device that offers high performance can be provided.

An electronic apparatus according to still another aspect of the invention includes the above-described electro-optic device.

With this structure, since the electro-optic device is capable of providing its function and offers high performance, an electronic apparatus that offers high performance can be provided.

### BRIEF DESCRIPTION OF THE DRAWINGS

The invention will be described with reference to the accompanying drawings, wherein like numbers reference like elements, and wherein:

FIG. 1 is a perspective view schematically showing a droplet discharge device;

FIG. 2 is a sectional schematic view illustrating a principal to discharge a liquid material by a piezoelectric method;

FIG. 3 is a plan view schematically showing a major part of a TFT array substrate;

FIG. 4A is a sectional view of the TFT, while FIG. 4B is a sectional view of a portion in which a gate wiring and a source wiring intersect in a plane;

FIG. 5 is a flowchart showing a wiring pattern forming method according to a first embodiment;

FIG. 6 is a schematic showing an example of a procedure to form a bank;

FIG. 7 is a schematic showing a plasma treatment device;

FIG. 8 is a schematic showing a procedure to deposit a functional liquid and a procedure to dry the functional liquid to form a wiring film;

FIG. 9 is a flowchart showing a wiring pattern forming method according to a second embodiment;

FIG. 10 is a schematic showing an example of a procedure to form a semiconductor layer and then form a bank.

FIG. 11 is a schematic showing a procedure to deposit a functional liquid and a procedure to dry the functional liquid to form a wiring film;

FIG. 12 is a plan view of the liquid crystal display according to a third embodiment of the invention viewed from an opposing substrate;

FIG. 13 is a sectional view along line H-H′ of FIG. 12;

FIG. 14 is an equivalent circuit view of the liquid crystal display;

FIG. 15 is a partially enlarged view of the liquid crystal display;

FIG. 16 is an exploded perspective view of a noncontact card medium;

FIG. 17 is an appearance diagram illustrating electronic apparatuses according to a fourth embodiment of the invention; and

FIG. 18 is a sectional view schematically showing a functional liquid in a concave portion formed by a bank when providing a wiring film by depositing the functional liquid to the concave portion.

### DESCRIPTION OF EXEMPLARY EMBODIMENTS

Embodiments of a thin-film pattern forming method according to the invention will now be described with reference to the accompanying drawings. The scale of the members and layers in the drawings is adequately changed so that they can be recognized.

### First Embodiment

A thin-film pattern forming method according to a first embodiment of the invention provides a wiring pattern formed by a conductive wiring film on a substrate. The wiring pattern forming method of this embodiment first provides a bank on the substrate so as to define a concave portion surrounded by the bank and having the same planar shape as the thin-film pattern. The method then discharges droplets of ink (functional liquid) for forming a wiring pattern that includes conductive particles from a discharge nozzle included in a droplet discharge head by droplet discharge to the concave portion so as to provide the wiring pattern formed by the conductive wiring film on the substrate. Here, the conductive wiring film corresponds to the first thin film. The wiring pattern corresponds to the thin-film pattern.

The ink (functional liquid) used as described above will now be described. The ink for forming a wiring pattern, which is a liquid material, is composed of a dispersion liquid in which conductive particles are dispersed in a dispersion medium. According to the present embodiment, examples of the conductive particles may include metal fine particles containing at least one of gold, silver, copper, palladium, and nickel; their oxides; and fine particles of a conductive polymer or a super-conductive material. These conductive particles may be used with their surfaces coated with an organic matter, for example, to improve their dispersibility. The diameter of the conductive particles is preferably within the range from 1 nm to 0.1 μm inclusive. Particles whose diameter is larger than 0.1 μm may cause clogging of the discharge nozzle included in the droplet discharge head, while particles whose diameter is smaller than 1 nm may make the volume ratio of the coating to the particles become so large that the ratio of the organic matter in the film becomes excessive.

Here, any dispersion medium that is capable of dispersing the above-described conductive particles and does not cause an aggregation can be used. Examples of the medium can include water; methanol, ethanol, propanol, butanol, and other alcohols; n-heptane, n-octane, decane, dodecane, tetradecane, toluene, xylene, cymene, durene, indene, dipentene, tetrahydronaphthalene, decahydronaphthalene, cyclohexylbenzene, and other hydro-carbon compounds; ethylene glycol dimethyl ether, ethylene glycol diethyl ether, ethylene glycol methyl ethyl ether, diethylene glycol dimethyl ether, diethylene glycol diethyl ether, diethylene glycol methyl ethyl ether, 1,2-dimethoxyethane, bis(2-methoxyethyl) ether, p-dioxane, and other ether compounds; and propylene carbonate, gamma-butyrolactone, N-methyl-2-pyrrolidone, dimethylformamide, dimethyl sulfoxide, cyclohexanone, and other polar compounds. Water, alcohols, hydro-carbon compounds, and ether compounds are preferably used in terms of particle dispersibility, dispersion-liquid stability, and applicability to droplet discharge. Among others, water and hydro-carbon compounds are more preferably used.

The surface tension of the dispersion liquid of the conductive particles is preferably within the range from 0.02 N/m to 0.07 N/m inclusive. A surface tension less than 0.02 N/m for discharging ink by droplet discharge increases the ink's wettability relative to a nozzle surface, so that a flying curve may possibly occur. A surface tension more than 0.07 N/m makes a meniscus shape at the tip of the nozzle unstable, making it difficult to control the amount and timing of discharge. To adjust the surface tension, a fluorine-, silicone- or nonionic-based surface tension adjuster, for example, may be added in a small amount to the dispersion liquid within a range not largely lowering the angle of contact with the substrate. The nonionic-based surface tension adjuster enhances the wettability of an ink with respect to a substrate, improves film leveling, and reduces minute film-surface roughness. The surface tension adjuster may include, as necessary, organic compounds, such as alcohol, ether, ester, and ketone.

The viscosity of the disperse liquid is preferably within the range from 1 mPa·s to 50 mPa·s inclusive. A viscosity lower than 1 mPa·s for discharging droplets of the ink by droplet discharge may contaminate the periphery of the nozzle due to ink leakage. A viscosity higher than 50 mPa·s may possibly cause nozzle clogging, making it difficult to discharge droplets smoothly.

Examples of the substrate on which the wiring pattern is provided may include a glass or quartz-glass substrate, a silicon wafer, a plastic film and a metal plate. Such examples may also include substrates whose surfaces are provided with a base layer, e.g. a semiconductor, metal, dielectric, or organic film.

Examples of droplet discharge techniques may include charge control, pressurized vibration, electromechanical conversion, electrothermal conversion, and electrostatic suction. The charge control is a method to apply electric charges to a material so as to discharge the material from a nozzle while controlling its flying direction with a deflection electrode. The pressurized vibration is a method to discharge at a nozzle tip by applying an extra-high voltage of approximately 30 kg/cm² to the material. If no control voltage is applied, the material goes straight ahead so as to be discharged from the discharge nozzle. If a control voltage is applied, the electrostatic repulsion within the material causes the dispersion of the material, thereby discharging no material from the discharge nozzle. The electromechanical conversion is a method that uses the deformation characteristic of piezoelectric elements in response to a pulsed electric signal. The method applies pressure to a space storing a material with an elastic material therebetween by deforming a piezoelectric element and pushes the material out of the space to discharge it from a discharge nozzle.

The electrothermal conversion is a method that evaporates a material rapidly with a heater provided in a space storing the material so as to produce bubbles, thereby discharging the material in the space by means of pressure of the bubbles. The electrostatic attraction is a method that applies micro pressure to a space storing a material so as to form a meniscus of the material at a discharge nozzle. Electrostatic attraction is then applied to pull out the material. Alternatively, a method that uses fluid viscosity change caused by an electric field, and a method that uses electric discharge sparks can also be employed. The droplet discharge methods have the advantage of adequately placing a material in a desired amount at a desired location with little waste in the use of the material. An amount of a liquid material droplet discharged by the droplet discharge methods is, for example, from 1 to 300 nanograms.

A device manufacturing apparatus for manufacturing a device according to an embodiment of the present invention will now be described. As this device manufacturing apparatus, a droplet discharge device (inkjet device) is used that discharges droplets from a droplet discharge head to a substrate so as to manufacturing a device.

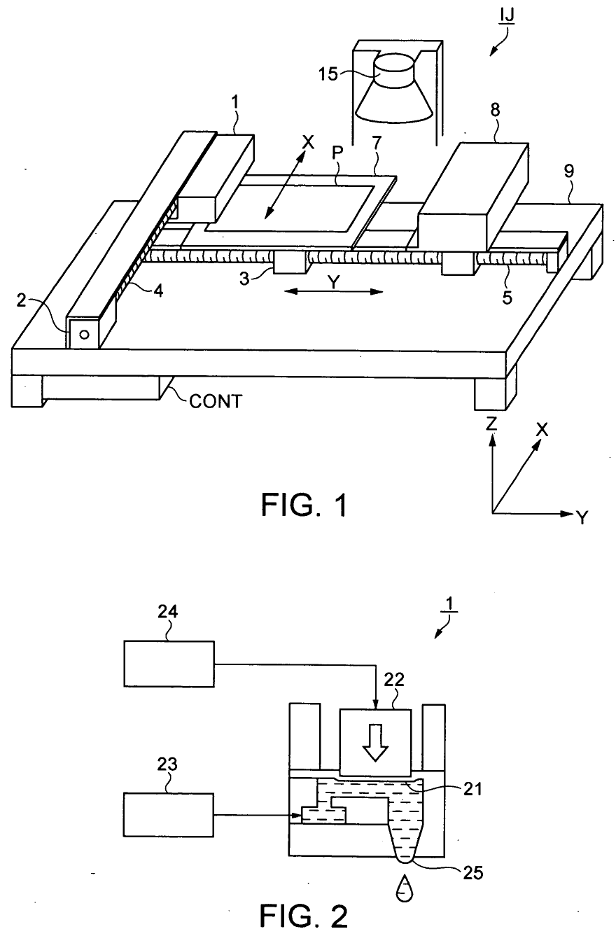

FIG. 1 is a perspective view schematically showing a droplet discharge device IJ. Referring to FIG. 1, the droplet discharge device IJ includes a droplet discharge head 1, an X-axis direction drive axis 4, a Y-axis guide axis 5, a controller CONT, a stage 7, a cleaning mechanism 8, a base 9, and a heater 15.

The stage 7 supports a substrate P to which an ink is provided by the droplet discharge device IJ and includes a fixing mechanism (not shown) for fixing the substrate P to a reference position.

The droplet discharge head 1 is a multi-nozzle droplet discharge head including a plurality of discharge nozzles. The longitudinal direction of the head coincides with the X-axis direction. The plurality of discharge nozzles are disposed at a fixed interval in the X-axis direction on a lower surface of the droplet discharge head 1. The ink containing conductive particles is discharged from the discharge nozzles included in the droplet discharge head 1 to the substrate P supported by the stage 7.

Coupled to the X-axis direction drive axis 4 is an X-axis direction drive motor 2. The X-axis direction drive motor 2 is a stepping motor, for example, and rotates the X-axis direction drive axis 4 when the controller CONT supplies a driving signal in the X-axis direction. The X-axis direction drive axis 4 rotates so as to move the droplet discharge head 1 in the X-axis direction.

The Y-axis guide axis 5 is fixed so as not to move with respect to the base 9. The stage 7 is equipped with a Y-axis direction drive motor 3. The Y-axis direction drive motor 3 is a stepping motor, for example, and moves the stage 7 in the Y-axis direction when the controller CONT supplies a driving signal in the Y-axis direction.

The controller CONT supplies a voltage for controlling droplet discharge to the droplet discharge head 1. The controller CONT also supplies a drive pulse signal for controlling the movement of the droplet discharge head 1 in the X-axis direction to the X-axis direction drive motor 2, and a drive pulse signal for controlling the movement of the stage 7 in the Y-axis direction to the Y-axis direction drive motor 3.

The cleaning mechanism 8 cleans the droplet discharge head 101 and includes a Y-axis direction drive motor (not shown). The cleaning mechanism 8 moves along the Y-axis direction guide axis 5 with the drive of this Y-axis direction drive motor. The controller CONT also controls the movement of the cleaning mechanism 8.

Here, the heater 15 is a means to apply heat treatment to the substrate P by lamp annealing so as to evaporate and dry a solvent contained in the ink applied on the substrate P. The controller CONT also controls turning on and off of the heater 15.

The droplet discharge device IJ discharges droplets to the substrate P while relatively scanning the droplet discharge head 1 and the stage 7 supporting the substrate P. In the following description, the Y-axis direction is referred to as a scan direction and the X-axis direction perpendicular to the Y-axis direction is referred to as a non-scan direction. Therefore, the discharge nozzles of the droplet discharge head 1 are disposed at a fixed interval in the X-axis direction, which is the non-scan direction. While the droplet discharge head 1 is disposed at right angle to the moving direction of the substrate P in FIG. 1, the angle of the droplet discharge head 1 may be adjusted so as to intersect the moving direction of the substrate P. Accordingly, a pitch between the nozzles can be adjusted by adjusting the angle of the droplet discharge head 1. Also, a distance between the substrate P and the surface of the nozzles may be arbitrarily adjusted.

FIG. 2 is a diagram illustrating a principal to discharge a liquid material by a piezoelectric method. Referring to FIG. 2, a piezoelectric element 22 is disposed adjacent to a liquid chamber 21 that stores a liquid material (ink for forming a wiring pattern, i.e. function liquid). To the liquid chamber 21, the liquid material is supplied through a liquid material supply system 23 including a material tank that stores the liquid material. The piezoelectric element 22 is coupled to a driving circuit 24. Through this driving circuit 24, a voltage is applied to the piezoelectric element 22, thereby deforming the piezoelectric element 22. Thus, the liquid chamber 21 is deformed to discharge the liquid material from a discharge nozzle 25. In this case, a strain amount of the piezoelectric element 22 is controlled by changing a value of the voltage that is applied. A strain velocity of the piezoelectric element 22 is also controlled by changing a frequency of the applied voltage. The droplet discharge employing this piezoelectric method advantageously has less effect on a material composition since no heat is applied to the material.

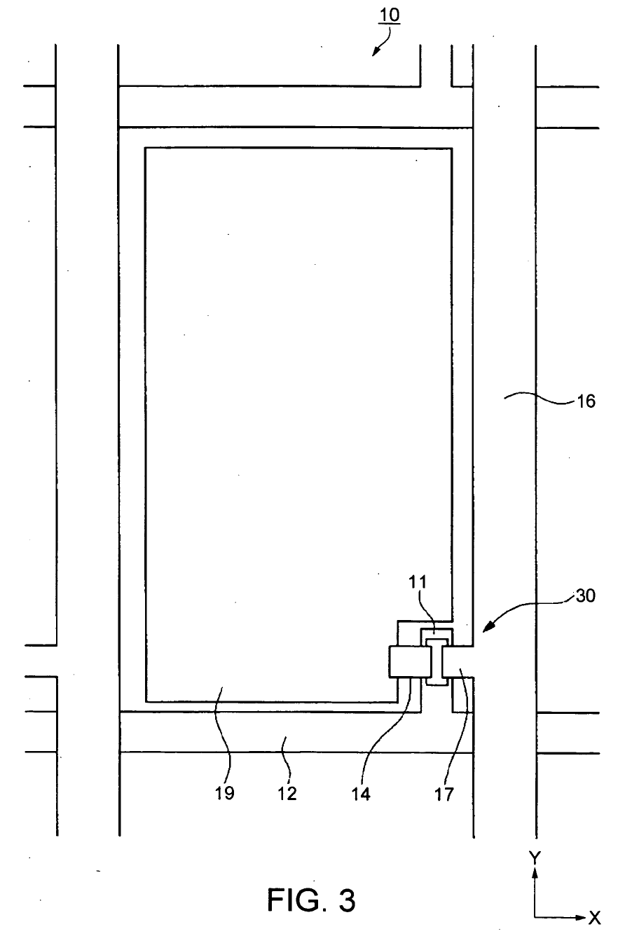

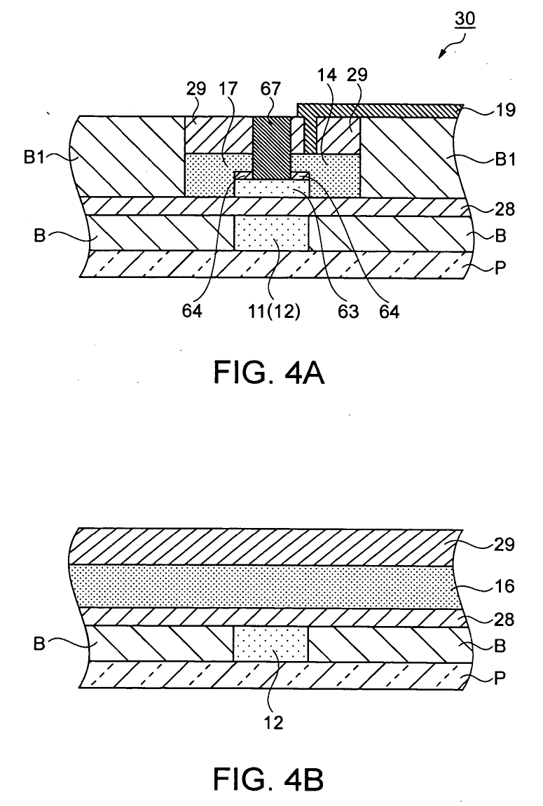

A thin film transistor (TFT) that is an example of devices manufactured with the wiring pattern forming method of the above-described embodiment will now be described. FIG. 3 is a plan view schematically showing part of a TFT array substrate including a TFT. FIG. 4A is a sectional view of the TFT, while FIG. 4B is a sectional view of a portion in which a gate wiring and a source wiring intersect in a plane.

Referring to FIG. 3, provided on this TFT array 10 including a TFT 30 are a gate wiring 12, a source wiring 16, a drain electrode 14, and a pixel electrode 19 that is electrically coupled to the drain electrode 14. The gate electrode 12 is provided to extend in the X-axis direction and part of it extends in the Y-axis direction. The part of the gate wiring 12 extending in the Y-axis direction is used as a gate electrode 11. The width of the, on the gate electrode 11 is smaller than the width of the gate wiring 12. The gate wiring 12 is formed by the wiring pattern forming method of the present embodiment. Part of the source wiring 16 extending in the Y-axis direction has a larger width, and is used as a source electrode 17.

Referring to FIG. 4, the gate wiring 12 and the gate electrode 11 are provided in a bank B on the substrate P. The gate wiring 12, the gate electrode 11 and the bank B are covered by an insulating film 28. Provided on the insulating film 28 are an activation layer 63 that is a semiconductor layer, the source wiring 16, the source electrode 17, the drain electrode 14, and a bank B1. The activation layer 63 is provided in a position largely facing with the gate electrode 11. The part of the activation layer 63 facing with the gate electrode 11 is used as a channel region. On the activation layer 63, bonding layers 64a and 64b are provided. The source electrode 17 is bonded to the activation layer 63 with the bonding layer 64a therebetween, while the drain electrode 14 is bonded to the activation layer 63 with the bonding layer 64b therebetween. One combination of the source electrode 17 and the other combination of the bonding layer 64a and the drain electrode 14 and the bonding layer 64b are insulated from each other by a bank 67 provided on the activation layer 63. The gate wiring 12 is insulated from the source wiring 16 by the insulating film 28, while the gate electrode 11 is insulated from the source electrode 17 and the drain electrode 14 by the insulating film 28. The source wiring 16, the source electrode 17 and the drain electrode 14 are covered by an insulating film 29. Part of the insulating film 29 that covers the drain electrode 14 is provided with a contact hole. The pixel electrode 19 that is coupled to the drain electrode 14 through this contact hole is provided on the upper surface of the insulating film 29.

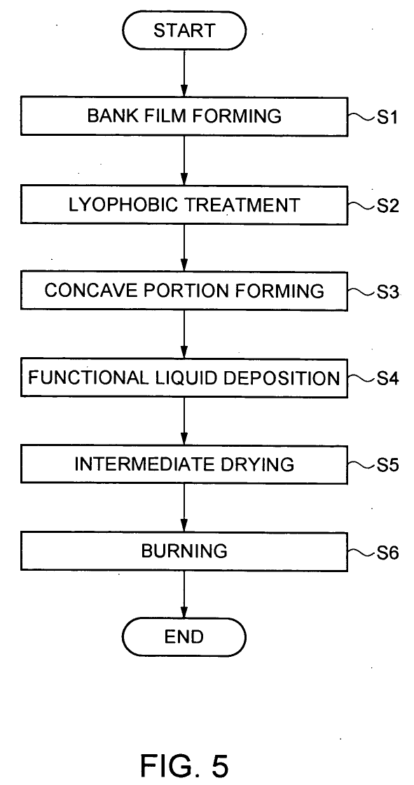

Steps to form a wiring pattern of the gate wiring of the TFT 30 by using the wiring pattern forming method of the present embodiment will now be described. FIG. 5 is a flowchart showing an example of the wiring pattern forming method of the present embodiment. According to the wiring pattern forming method of the present embodiment, a bank is provided on the substrate so as to define a concave portion surrounded by the bank and having the same planar shape as the thin-film pattern. Thus, a wiring pattern is formed by providing the ink for forming a wiring pattern in this concave portion and forming a wiring film on the substrate.

Step S1 is a bank film forming step for forming a bank film to provide a bank on the substrate. Subsequent Step S2 is a lyophobic treatment step for making the surface of the bank film lyophobic. Subsequent Step S3 is a concave portion forming step for etching the bank film so as to form a concave portion in accordance with the pattern of the gate wiring. Subsequent Step S4 is a functional liquid deposition step for depositing an ink between banks that have made lyophobic. Subsequent Step S5 is an intermediate drying step for eliminating at least part of ink liquid components. Subsequent Step S6 is a burning step for carrying out heat treatment for obtaining conductivity if conductive particles contained in the ink are an organic compound. The bank film corresponds to the second thin film.

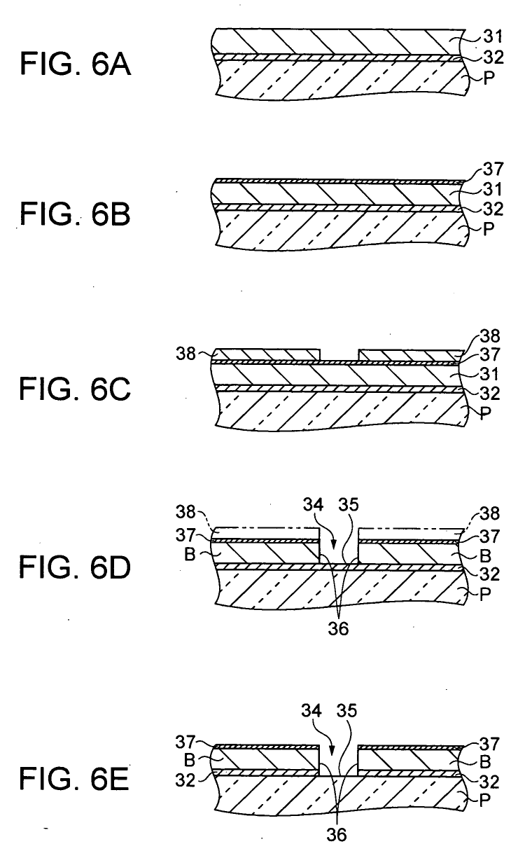

Each of the steps will now be described in detail. This embodiment uses a glass substrate as the substrate P. Step S1, the bank film forming step, will now be described. FIG. 6 is a schematic showing an example of a procedure to form a bank. In this bank film forming step, the substrate P is subjected to HMDS treatment prior to the application of a bank forming material. The HMDS treatment is the application of hexamethyldisilazane ((CH₃)₃SiNHSi(CH₃)₃) steam. This treatment provides an HMDS layer 32 on the substrate P. The layer serves as an adhesion layer increasing the adhesion between a bank B and the substrate P.

The bank functions as a partition member. The bank can be formed by any methods including photolithography and printing. For example, when employing photolithography, a bank forming material is applied by a predetermined method, such as spin coating, spray coating, roll coating, die coating, or dip coating. The bank forming material is thus applied on the HMDS layer 32 on the substrate P to a height of the bank, thereby providing a bank film 31 as shown in FIG. 6A.

The wiring pattern forming method according to the present embodiment uses a material with an affinity for the functional liquid as the bank forming material, i.e. the material for forming the bank film 31 in this bank film forming step. Examples of such materials with an affinity for the functional liquid may include spin-on glass films, diamond films and fluorinated amorphous carbon films containing any of polymer inorganic materials containing silicon in the structure of polysilazane, polysiloxane, siloxane resists, polysilane resists, etc., inorganic photosensitive materials, silica glass, alkylsiloxane polymer, alkylsilsesquioxane polymer, alkylsilsesquioxane polymer hydride, and polyarylether. Aerogel and porous silica may also be used as a bank forming material with an affinity for the functional liquid. The degree of the affinity of the bank forming material is preferably such that a contact angle with respect to the functional liquid is 20 degrees or less. If the contact angle exceeds 20 degrees, the affinity is possibly insufficient depending on the shape of a groove 34 that will be described below (see FIG. 6E).

Step S2, the lyophobic treatment step, will now be described. In this lyophobic treatment step, the bank film 31 is subjected to lyophobic treatment to making its surface lyophobic. As the lyophobic treatment, plasma treatment (CF₄ plasma treatment) using tetrafluoromethane as a process gas is employed. The CF₄ plasma treatment is carried out, for example, under the following condition: plasma power from 50 to 1000 W, a volume of tetrafluoromethane gas flow from 50 to 100 ml/min, a velocity of substrate transportation with respect to a plasma discharge electrode from 0.5 to 1020.0 mm/sec, and a substrate temperature from 70 to 90 degrees Celsius. The process gas is not limited to tetrafluoromethane, and other fluorocarbon gases, SF6 and SF5CF3 can also be used.

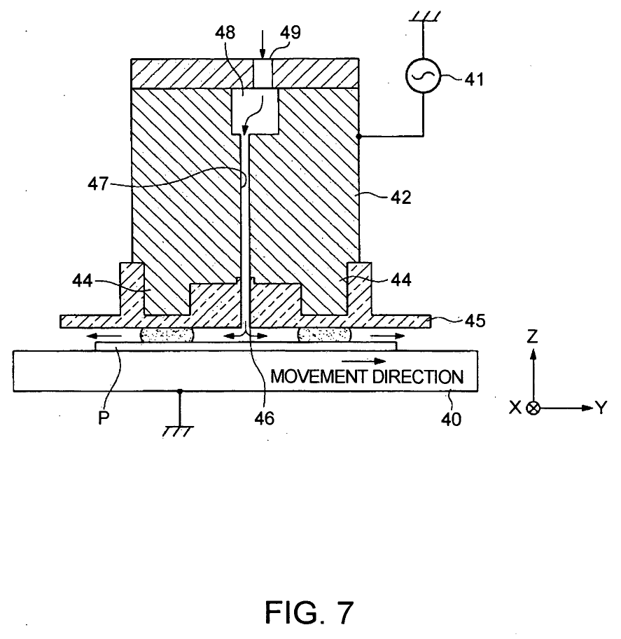

FIG. 7 is a schematic showing an example of a plasma treatment device used for CF₄ plasma treatment. The plasma treatment device shown in FIG. 7 includes an electrode 42 coupled to an alternating current power source 41, and a sample table 40. The sample table 40 supports the substrate P, which is a sample here, and is movable in the Y-axis direction. Provided to the lower surface of the electrode 42 are two electrical discharge generators 44, 44 parallel to each other and extending in the X-axis direction, which is orthogonal to the Y-axis direction, and a dielectric member 45 provided so as to surround each electrical discharge generator 44. The dielectric member 45 prevents an abnormal discharge of the electrical discharge generator 44. The lower surface of the electrode 42 including the dielectric member 45 is almost planar. There is a small space (discharge gap) between the electrical discharge generator 44 and the dielectric member 45, and the substrate P. At a central portion of the electrode 42, a gas vent 46 included in a process gas supply part that is elongated in the X-axis direction is provided. The gas vent 46 is coupled to a gas inlet 49 via a gas passageway 47 and an intermediate chamber 48 inside the electrode.

A predetermined gas including the process gas ejected from the gas vent 46 via the gas passageway 47 flows inside the space in or against the movement direction (i.e. the Y-axis direction) and is exhausted outside from the front and rear end of the dielectric member 45. At the same time, a predetermined voltage is applied from the alternating current power source 41 to the electrode 42, causing a gaseous discharge between the electrical discharge generators 44, 44 and the sample table 40. Plasma generated by this gaseous discharge produces excitation active species of the predetermined gas. Therefore, the whole surface of the bank film 13 provided on the substrate P that passes a discharge area is sequentially treated.

The predetermined gas is a mixture of tetrafluoromethane, which is the process gas, and a rare gas, such as helium (He) and argon (Ar), or an inert gas, such as nitrogen (N₂) to make an electrical discharge under a pressure near atmospheric pressure start easily and be maintained stably.

This lyophobic treatment provides a lyophobic treatment layer 37 on the surface of the bank film 31 as shown in FIG. 6B. Specifically, a fluorine group is introduced in the resin of the bank film to form the lyophobic treatment layer, thereby providing a high repellency to the functional liquid. The degree of the repellency of the lyophobic treatment layer 37 is preferably such that a contact angle of the functional liquid is 90 degrees or more. If the contact angle is less than 90 degrees, the functional liquid tends to remain on the upper surface of the bank B.

Step S3, the concave portion forming step, will now be described. In this concave portion forming step, part of the bank film 31 is removed by photolithography so as to form the bank B and the groove 34 that is a concave portion surrounded by the bank B. First, a resist layer is applied on the bank film 31 that has been formed in Step S1, the bank film forming step. The resist is then exposed to light and developed using a mask aligned with a bank shape (wiring pattern), so that a resist 38 can remain as aligned with the bank shape. Finally, part of the bank film 31 that is not covered by the resist 38 is removed by etching, and the resist 38 is then removed. Accordingly, the bank B and the groove 34 that is a concave portion surrounded by the bank B are provided as shown in FIG. 6D.

As the bank B is provided on the substrate P, hydrofluoric acid treatment is carried out. The hydrofluoric acid treatment involves etching with a 2.5% hydrofluoric acid solution so as to remove the HMDS layer 32 between one bank B and another adjacent bank B. In the hydrofluoric acid treatment, the bank B functions as a mask. The HMDS layer 32 that is an organic matter on a bottom 35 of the groove 34 between one bank B and another adjacent bank B is removed and the substrate P is exposed as shown in FIG. 6E. Glass and quartz glass used as the substrate P provided with the wiring pattern have an affinity for the functional liquid. Therefore, the bottom 35 where the substrate P is exposed has an affinity for the functional liquid.

Accordingly, the bank B and the groove 34 that is a concave portion surrounded by the bank B are provided as shown in FIG. 6E, which completes Step S3, the concave portion forming step. The upper surface of the bank B formed in this concave portion forming step is provided with the lyophobic treatment layer 37 formed in the above-described lyophobic treatment step. Therefore, the upper surface of the bank B is repellent to the functional liquid. In contrast, a side 36 of the groove 34 that is a concave portion and also of the bank B has an affinity for the functional liquid, since the material for forming the bank film 31 with an affinity for the functional liquid is exposed there. As mentioned above, the bottom 35 has an affinity for the functional liquid. In other words, the groove 34 has the side 36 and the bottom 35 both of which have an affinity for the functional liquid.

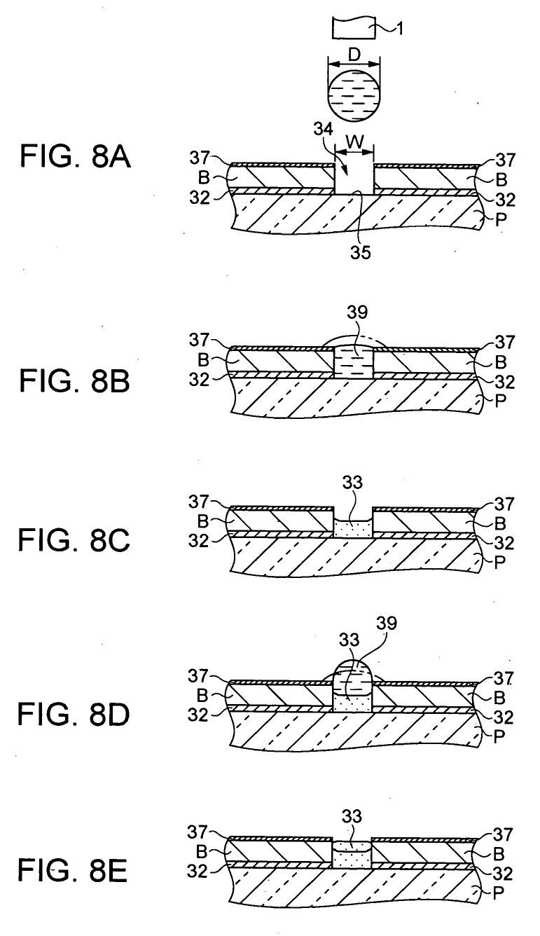

Step S4, the functional liquid deposition step, will now be described. FIG. 8 is a schematic showing an example of a procedure to deposit a functional liquid and a procedure to dry the deposited functional liquid to form a wiring film. In this functional liquid deposition step, droplets of the ink for forming a wiring pattern are deposited between one bank B and another adjacent bank B on the substrate P by droplet discharge with the droplet discharge device IJ. Here, an organic silver compound is used as a conductive material, and an ink containing the organic silver compound using diethylene glycol diethyl ether as a solvent (dispersion medium) is discharged. In this functional liquid deposition step, as shown in FIG. 8A, the ink containing the material for forming a wiring pattern are deposited in the form of droplets from the droplet discharge head 1. The droplet discharge head 1 discharges droplets of the ink toward the groove 34 between one bank B and another adjacent bank B so as to deposit the ink in the groove 34. Since the area for forming a wiring pattern (i.e. the groove 34) to which droplets are discharged is surrounded by the banks B, B, it is possible to prevent the droplets from flowing out of the predetermined area.

In the present embodiment, the width W of the groove 34 between the banks B, B (here, the width at the opening of the groove 34) is set at almost the same as the diameter D of ink (functional liquid) droplets. Discharging droplets is preferably carried out at a temperature of 60 degrees Celsius or less and a humidity of 80% or less. This condition allows the discharge nozzles of the droplet discharge head 1 to stably discharge droplets without clogging.

Since the diameter D of droplets discharged from the droplet discharge head 1 and deposited in the groove 34 is almost the same as the width W of the groove 34, part of them may be placed on the banks B, B as shown with the chain double-dashed line in FIG. 8B. Even in such a case, the banks B, B, whose surfaces are lyophobic, repel the ink placed thereon. Further driven by a capillary phenomenon, most ink 39 flows into the groove 34 as shown with the solid line in FIG. 8B.

The ink discharged to the groove 34 or flowing from the banks B, B fill the groove 34 evenly, since it tends to spread on the bottom 35 and the side 36, which are lyophilic.

Step S4, the intermediate drying step, will now be described. Drying to eliminate the dispersion medium and ensure a film thickness may follow the discharge of droplets on the substrate P, if necessary. This drying treatment may be conducted by lamp annealing as well as with a typical hot plate, electric furnace, or the like, to heat the substrate P. Examples of light sources used for lamp annealing are not particularly limited, and may include infrared lamps, xenon lamps, YAG laser, argon laser, carbon dioxide laser, and XeF, XeCl, XeBr, KrF, KrCl, ArF or ArCl excimer laser. While such light sources generally have an output range from 10 W to 5000 W inclusive, a range from 100 W to 1000 W inclusive is sufficient for the present embodiment. After this intermediate drying step is completed, a circuit wiring film 33 that is a wiring film for forming a wiring pattern is provided as shown in FIG. 8C. The wiring pattern formed by this circuit wiring film 33 serves as the gate wiring 12 and the gate electrode 11 shown in FIGS. 3 and 4.

If one cycle of the functional liquid deposition step and the intermediate drying step does not provide the circuit wiring film 33 to a necessary thickness, these steps are repeated. When the functional liquid is left on the circuit wiring film 33, the ink 39 beyond the capacity of the groove 34 is repelled by the lyophobic surface of the bank B and piled on the groove 34 as shown in FIG. 8D. By drying the ink 39 in the groove 34 or piled on the groove 34, ink droplets are deposited to form the circuit wiring film 33 to a large thickness as shown in FIG. 8E. Here, a necessary thickness can be achieved by appropriately setting the thickness of the circuit wiring film 33 provided in one cycle of the functional liquid deposition step and the intermediate drying step and the number of repetition of these steps.

Step S6, the burning step, will now be described. A dried film after the intermediate drying step, if it is an organic silver compound, requires heat treatment to obtain conductivity, thereby removing organic matters in the compound and causing silver particles to remain. For this purpose, the substrate is subjected to heat and/or light treatment after droplet discharge.

While the heat and/or light treatment can be conducted in an environment of an inert gas, such as nitrogen, argon, and helium, if required instead of in the atmosphere. The temperature for the heat and/or light treatment is appropriately set depending on the boiling point (vapor pressure) of the disperse medium, the type and pressure of atmospheric gas, thermal behavioral properties including particle dispersibility and oxidizability, the presence and volume of the coating material, and base-material heat resistance temperature, for example. In the present embodiment, the ink that has been discharged to form a pattern is subjected to 300-minute burning at 280 to 300 degrees Celsius with a clean oven in the atmosphere. For example, eliminating organic matters in the organic silver compound requires burning at about 200 Celsius. When using a plastic substrate, for example, burning is preferably in a temperature range from room temperature to 250 degrees Celsius inclusive. The above-described procedure secures electrical contact between particles in the dried film after droplet discharge, and the film is turned to be conductive.

The first embodiment provides the following effects.

(1) The wiring pattern forming method according to the present embodiment uses a material for forming the bank B with an affinity for the functional liquid. Accordingly, the side 36 of the bank B and also of the groove 34 is lyophilic. Having the side 36 that is lyophilic allows the functional liquid in the groove 34 to fill the groove 34 easily. Therefore, the circuit wiring film 33, which is formed by drying the functional liquid, has a cross sectional shape that fills the groove 34.

(2) The bank film 31 is subjected to lyophobic treatment to making its surface lyophobic. Accordingly, the upper surface of the bank B surrounding the groove 34 for forming the circuit wiring film 33, which is formed by etching the bank film 31, is repellent to the functional liquid. Since the surface of the bank B is lyophobic, part of the functional liquid placed on the bank B is repelled by the bank B, and thus flows into the groove 34.

(3) Etching of the bank film 31 to provide the bank B and the groove 34 follows the lyophobic treatment to the surface of the bank film 31 on the substrate P. Accordingly, the side 36 of the bank B and also of the groove 34 is not subjected to the lyophobic treatment, and thereby the forming material remains lyophilic. Having the side 36 that is lyophilic allows the functional liquid in the groove 34 to fill the groove 34 easily. Therefore, the circuit wiring film 33, which is formed by drying the functional liquid, has a cross sectional shape that fills the groove 34.

(4) The functional liquid for forming the gate wiring 12 and the gate electrode 11 in the groove 34 spreads on the side 36 of the groove 34, which is lyophilic, and thus fills the groove 34. Drying the functional liquid filling the groove 34 provides the gate wiring 12 and the gate electrode 11 to an even thickness with a sufficient sectional area.

### Second Embodiment

A thin-film pattern forming method according to a second embodiment of the invention will now be described. In the present embodiment, a method for forming a wiring pattern that forms a circuit wiring further on the wiring pattern formed by the above-described wiring pattern formed in the first embodiment will be described. The droplet discharge method and device used in the present embodiment are fundamentally the same as those employed in the first embodiment.

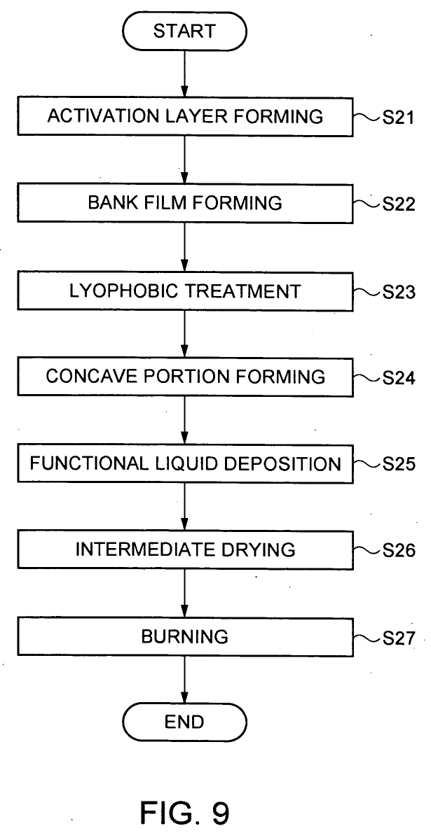

FIG. 9 is a flowchart showing an example of the wiring pattern forming method of the present embodiment. According to the wiring pattern forming method of the present embodiment, a bank is provided on the substrate so as to define a concave portion surrounded by the bank and having the same planar shape as the thin-film pattern. Thus, a wiring pattern is formed by providing the ink for forming a wiring pattern, which is described in the first embodiment, in this concave portion and forming a wiring film on the substrate.

Step S21 is an activation layer forming step for forming an activation layer that is a semiconductor layer, for example. Subsequent Step S2 is a bank film forming step for forming a bank film to provide a bank on the surface. Subsequent Step S23 is a lyophobic treatment step for making the surface of the bank film lyophobic. Subsequent Step S24 is a concave portion forming step for etching the bank film so as to form a concave portion in accordance with the pattern of a gate wiring. Subsequent Step S25 is a functional liquid deposition step for depositing an ink between banks that have made lyophobic. Subsequent Step S26 is an intermediate drying step for eliminating at least part of ink liquid components. Subsequent Step S27 is a burning step for carrying out heat treatment for obtaining conductivity if conductive particles contained in the ink are an organic silver compound.

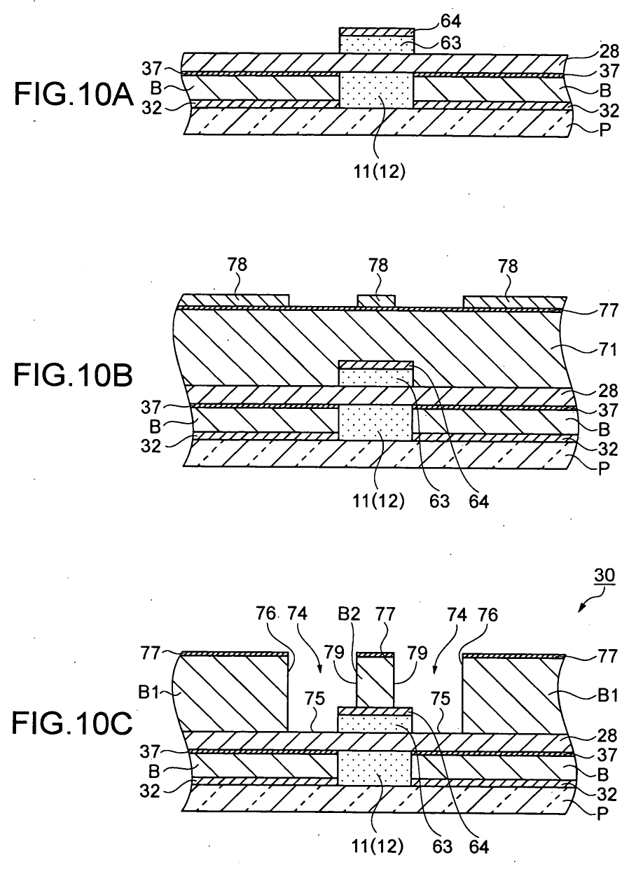

Each of the steps will now be described in detail. According to the present embodiment, a wiring pattern including a source wiring and a drain electrode is further provided on the wiring pattern of the gate wiring formed in the first embodiment. FIG. 10 is a schematic showing an example of a procedure to form a semiconductor layer and then form a bank.

Step S21, the activation layer forming step, is to form a gate insulating film (the insulating film 28), an activation layer 63 that is a semiconductor layer, and a bonding layer 64 sequentially by plasma chemical vapor deposition (CVD) as shown in FIG. 10A. A silicon nitride film is used for the insulating film 28, an amorphous silicon film for the activation layer 63, and an n+ silicon film for the bonding layer 64. Appropriate material gases and plasma conditions are adopted. While CVD requires a heat history at 300 to 350 degrees Celsius, using a silica glass material having a basic structure with a main chain mainly composed of silicon and a carbohydrate side chain, for example, for the bank may solve transparency and heat resistance problems.

The bank functions as a partition member. The bank can be formed by any methods including lithography and printing. For example, when employing photolithography, a bank forming material is applied by a predetermined method, such as spin coating, spray coating, roll coating, die coating, or dip coating. The bank forming material is thus applied on the insulating film 28 on the substrate P to a height that covers the activation layer 63 and the bonding layer 64, thereby providing a bank film 71 as shown in FIG. 10B.

The wiring pattern forming method according to the present embodiment uses a material with an affinity for the functional liquid as the bank forming material, i.e. the material for forming the bank film 71 in this bank film forming step. Examples of such materials with an affinity for the functional liquid may include spin-on glass films, diamond films and fluorinated amorphous carbon films containing any of polymer inorganic materials containing silicon in the structure of polysilazane, polysiloxane, siloxane resists, polysilane resists, etc., inorganic photosensitive materials, silica glass, alkylsiloxane polymer, alkylsilsesquioxane polymer, alkylsilsesquioxane polymer hydride, and polyarylether. Aerogel and porous silica may also be used as a bank forming material with an affinity for the functional liquid. The degree of the affinity of the bank forming material is preferably such that a contact angle of the functional liquid is 20 degrees or less. If the contact angle exceeds 20 degrees, the affinity is possibly insufficient depending on the shape of a groove 74 that will be described below (see FIG. 10C).

Step S23, the lyophobic treatment step, will now be described. In this lyophobic treatment step, the bank film 71 is subjected to lyophobic treatment to making its surface lyophobic. As the lyophobic treatment, plasma treatment (CF₄ plasma treatment) using tetrafluoromethane as a process gas is employed. The CF₄ plasma treatment is carried out, for example, under the following condition: plasma power from 50 to 1000 W, a volume of tetrafluoromethane gas flow from 50 to 100 ml/min, a velocity of substrate transportation with respect to a plasma discharge electrode from 0.5 to 1020.0 mm/sec, and a substrate temperature from 70 to 90 degrees Celsius. The process gas is not limited to tetrafluoromethane, and other fluorocarbon gases, SF6 and SF5CF3 can also be used. This CF₄ plasma treatment may use the plasma treatment device described in the first embodiment referring to FIG. 7.

This lyophobic treatment provides a lyophobic treatment layer 77 on the surface of the bank film 71 as shown in FIG. 10B. Specifically, a fluorine group is introduced in the resin of the bank film to form the lyophobic treatment layer, thereby providing a high repellency to the functional liquid. The degree of the repellency of the lyophobic treatment layer 77 is preferably such that a contact angle of the functional liquid is 90 degrees or more. If the contact angle is less than 90 degrees, the functional liquid tends to remain on the upper surface of the bank B.

Step S24, the concave portion forming step, will now be described. In this concave portion forming step, part of the bank film 71 is eliminated by photolithography so as to form banks B1 and B2 and the groove 74 that is a concave portion surrounded by the banks B1 and B2. First, a resist layer is applied on the bank film 71 that has been formed in Step S22, the bank film forming step. The resist is then exposed to light and developed using a mask aligned with a bank shape (wiring pattern), so that a resist 78 can remain as aligned with the bank shape. Finally, part of the bank film 71 that is not covered by the resist 78 is removed by etching, and the resist 78 is then removed.

Accordingly, the banks B1 and B2 and the groove 74 that is a concave portion surrounded by the banks B1 and B2 are provided as shown in FIG. 10C, which completes Step S24, the concave portion forming step. The upper surfaces of the banks B1 and B2 formed in this concave portion forming step are provided with the lyophobic treatment layer 77 formed in the above-described lyophobic treatment step. Therefore, the upper surfaces of the banks B1 and B2 are repellent to the functional liquid. In contrast, a side 76 of the groove 74 that is a concave portion and also of the bank B1 has an affinity for the functional liquid, since the material for forming the bank film 71 with an affinity for the functional liquid is exposed there. In the same manner, a side 79 of the groove 74 that is a concave portion and also of the bank B2 has an affinity for the functional liquid, since the material for forming the bank film 71 with an affinity for the functional liquid is exposed there. A bottom 75 that is the surface of the insulating film 28 and the bonding layer 64 have an affinity for the functional liquid. In other words, the groove 74 has the sides 76, 79 and the bottom 75 all of which have an affinity for the functional liquid.

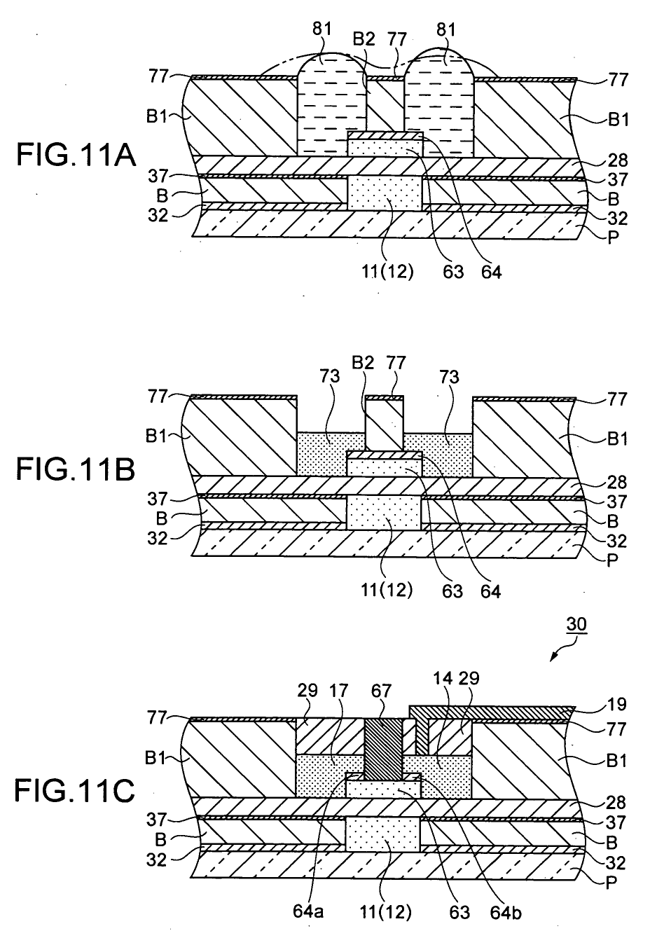

Step S25, the functional liquid deposition step, will now be described. FIG. 11 is a schematic showing an example of a procedure to deposit ink (functional liquid) and a procedure to dry the deposited ink to form a wiring film. In this functional liquid deposition step, droplets of the ink for forming a wiring pattern are deposited by droplet discharge with the above-described droplet discharge device IJ in the concave portion defined by the banks B1 and B2. Here, an organic silver compound is used as a conductive material, and an ink containing the organic silver compound using diethylene glycol diethyl ether as a solvent (dispersion medium) is discharged. In this functional liquid deposition step, the ink containing the material for forming a wiring pattern are deposited in the form of droplets from the droplet discharge head 1. The droplet discharge head 1 discharges droplets of the ink toward the groove 74 defined by the banks B1 and B2 so as to deposit the ink in the groove 74. Since the area for forming a wiring pattern (i.e. the groove 74) to which the droplets are discharged is surrounded by the banks B1 and B2, it is possible to prevent the droplets from flowing out of the predetermined area.

The width of the groove 74 between the banks B1 and B2 (here, the width at the opening of the groove 74) is set at almost the same as the diameter D of ink (functional liquid) droplets. Discharging droplets is preferably carried out at a temperature of 60 degrees Celsius or less and a humidity of 80% or less. This condition allows the discharge nozzles of the droplet discharge head 1 to stably discharge droplets without clogging.

Since the diameter D of droplets discharged from the droplet discharge head 1 and deposited in the groove 74 is almost the same as the width of the groove 74, part of them may be placed on the banks B1 and B2 as shown with the chain double-dashed line in FIG. 11A. Even in such a case, the banks B1 and B2, whose surfaces are lyophobic, repel the ink placed thereon. Further driven by a capillary phenomenon, most ink 81 flows into the groove 74 as shown with the solid line in FIG. 11A. The functional liquid beyond the capacity of the groove 74 is repelled by the lyophobic surfaces of the banks B1 and B2 and piled on the groove 74.

The ink discharged to the groove 74 or flowing from the banks B1 and B2 fill the groove 74 evenly, since it tends to spread on the bottom 75 and the side 76, which are lyophilic.

Step S26, the intermediate drying step, will now be described. Drying to eliminate the dispersion medium and ensure a film thickness may follow the discharge of droplets on the substrate P, if necessary. Step S26, the intermediate drying step, is fundamentally the same as Step S26, the intermediate drying step, in the first embodiment. In this intermediate drying step S26, a circuit wiring film 73 that is a wiring film for forming a wiring pattern is provided as shown in FIG. 11B. According to the present embodiment, the wiring pattern formed by this circuit wiring fl1m 73 serves as the gate wiring 16, the gate electrode 17, and the drain electrode 14 shown in FIGS. 3 and 4.

If one cycle of the functional liquid deposition step and the intermediate drying step does not provide the circuit wiring film 73 to a necessary thickness, these steps are repeated. Here, a necessary thickness can be achieved by appropriately setting the thickness of the circuit wiring film 73 provided in one cycle of the functional liquid deposition step and the intermediate drying step and the number of repetition of these steps.

Step S27, the burning step, will now be described. A dried film after the intermediate drying step, if it is an organic silver compound, requires heat treatment to obtain conductivity, thereby removing organic matters in the compound and causing silver particles to remain. For this purpose, the substrate is subjected to heat and/or light treatment after droplet discharge.

Step S27, the burning step, is fundamentally the same as Step S6, the burning step, in the first embodiment. This burning step S27 secures electrical contact between particles in the dried film, and the film is turned to be conductive. This procedure secures electrical contact between particles in the dried film after droplet discharge, and the film is turned to be conductive.

Subsequently, the bank B2 is removed, and the bonding layer 64 is etched so as to separate into a bonding layer 64a that bonds the source electrode 17 and a bonding layer 64b that bonds the drain electrode 14. The bank 67 to insulate the source electrode 17 and the drain electrode 14 is provided in an area from which the bank B2 has been removed and an area from which the bonding layer 64 has been removed. Also, the insulating film 29 is provided so as to fill the groove 74 in which the source electrode 17 and the drain electrode 14 are provided. This procedure provides a flat upper surface made up of the bank B1, the bank 67, and the insulating film 29. Here, the bank 67 and the insulating film 29 may be made of the same material. In this case, it is possible to insulate the source electrode 17 and the drain electrode 14 by placing the insulating film 29 so as to fill the groove 74. Alternatively, before forming the bank film 71, the bonding layer 64 may be etched so as to separate into the bonding layer 64a that bonds the source electrode 17 and the bonding layer 64b that bonds the drain electrode 14.

Part of the insulating film 29 that covers the drain electrode 14 is provided with a contact hole. The pixel electrode 19 made of indium tin oxide (ITO) that is coupled to the drain electrode 14 through this contact hole is provided on the upper surface of the insulating film 29. Then the gate wiring is provided as described in the first embodiment. Furthermore, the source wiring and the drain wiring are provided as described in the present embodiment. Accordingly, the TFT array substrate 10 including the TFT 30 is provided.

The second embodiment provides the following effects.

(1) The wiring pattern forming method according to the present embodiment uses a material for forming the banks B1, B2 with an affinity for the functional liquid. Accordingly, the sides 76, 79 of the banks B1, B2 and of the groove 74 are made lyophilic. Having the sides 76, 79 that are lyophilic allows the functional liquid in the groove 74 to fill the groove 74 easily. Therefore, the circuit wiring film 73, which is formed by drying the functional liquid, has a cross sectional shape that fills the groove 74.

(2) The bank film 71 is subjected to lyophobic treatment to making its surface lyophobic. Accordingly, the upper surfaces of the banks B1, B2 surrounding the groove 74 for forming the circuit wiring film 73, are repellent to the functional liquid. Since the surfaces of the banks B1, B2 are lyophobic, part of the functional liquid placed on the banks B1, B2 is repelled by the banks B1, B2, and thus flows into the groove 74.

(3) Etching of the bank film 71 to provide the banks B1, B2 and the groove 74 follows the lyophobic treatment to the surface of the bank film 71. Accordingly, the sides 76, 79 of the banks B1, B2 and of the groove 74 are not subjected to the lyophobic treatment, and thereby the forming material remains lyophilic. Having the sides 76, 79 that are lyophilic allows the functional liquid in the groove 74 to fill the groove 74 easily. Therefore, the circuit wiring film 73, which is formed by drying the functional liquid, has a cross sectional shape that fills the groove 74.

(4) The functional liquid for forming the source electrode 17 and the drain electrode 14 in the groove 74 spreads on the side 79 of the groove 74, which is lyophilic, to the edge of the bank B2. Drying the functional liquid spreading to the edge of the bank B2 provides the source electrode 17 and the drain electrode 14 to an even thickness to the edge of the bank B2 with a sufficient sectional area. In other words, the source electrode 17 and the drain electrode 14 near an area that bonds the activation layer 63 with the bonding layers 64a, 64b therebetween are formed as a conductive film provided to an even thickness with a sufficient sectional area.

### Third Embodiment

A liquid crystal display as an example of an electro-optic device according to a third embodiment of the invention will now be described. This liquid crystal display according to the present embodiment includes a TFT having a circuit wiring provided by the thin-film pattern forming method according to the first and second embodiments.

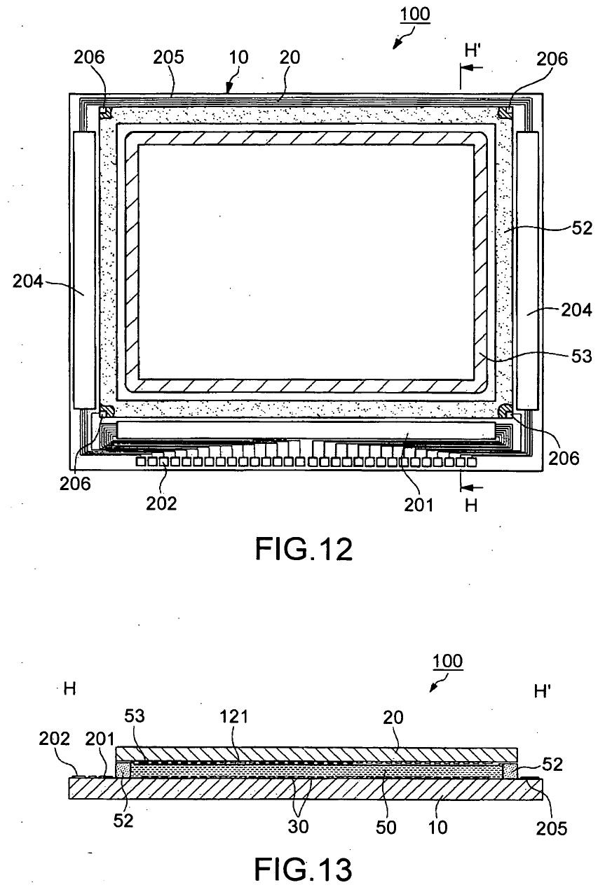

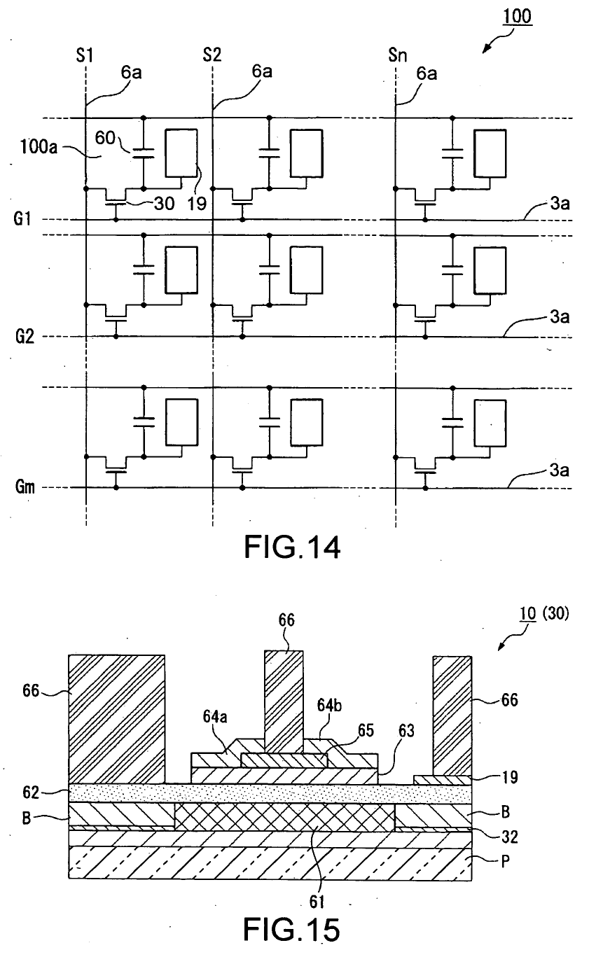

FIG. 12 is a plan view of the liquid crystal display according to the present embodiment with each component viewed from an opposing substrate. FIG. 13 is a sectional view along line H-H′ of FIG. 12. FIG. 14 is an equivalent circuit view showing each element, wiring, etc. in a plurality of pixels arranged in a matrix in an image display area of the liquid crystal display. FIG. 15 is a partially enlarged view of the liquid crystal display. It should be noted that different scales are used for the layers and members in the drawings, so that the layers and members can be recognized.

Referring to FIGS. 12 and 13, this liquid crystal display (electro-optic device) 100 according to the present embodiment, a pair of the TFT array substrate 10 and an opposing substrate 20 that are make a pair are bonded to each other with a photocuring sealant 52. In an area defined by this sealant 52, a liquid crystal 50 is sealed and retained. The sealant 52 is provided in a closed frame in an area included in the substrate surface.

In the area where the sealant 52 is provided, a peripheral light-blocking film 53 made of a light blocking material is provided. In an area outside the sealant 52, a data line driving circuit 201 and a mount terminal 202 are provided along one side of the TFT array substrate 10. Provided along two sides adjacent to the one side are scanning line driving circuits 204. Provided along another side of the TFT array substrate 10 are a plurality of wiring 205 to couple the scanning line driving circuits 204 provided to the both sides of the display area. At one or more of the corners of the opposing substrate 20, an inter-substrate conductive material 206 to provide electrical conductivity between the TFT array substrate 10 and the opposing substrate 20.

Hear, instead of providing the data line driving circuit 201 and the scanning line driving circuits 204 on the TFT array substrate 10, electrical and mechanical connection may be provided by a group of terminals and an anisotropic conductive film that are provided around a tape automated bonding (TAB) substrate on which a driving LSI is mounted and the TFT array substrate 10. Note that a retardation film, a polarizer, etc., included in the liquid crystal display 100 are aligned in a predetermined direction (not shown) depending on the type of the liquid crystal 50, that is, operation modes including twisted nematic and super twisted nematic modes and normally white and normally black modes. If the liquid crystal display 100 is provided as a color display, red (R), green (G) and blue (B) color filters, for example, and their protective films are provided in an area in the opposing substrate 20 opposing to each pixel electrode in the TFT array substrate 10 that will be described below.

In the image display area of the liquid crystal display 10 of having the above-described structure, as shown in FIG. 14, a plurality of pixels 100a are arranged in a matrix. Each of the pixels 100a is provided with the TFT (switching element) 30 for switching pixels. To the source of the TFT 30, a data line 6a that supplies pixel signals S1 through Sn is electrically coupled. The pixel signals S1 through Sn written in the data line 6a may be supplied in this order or in groups for a plurality of adjacent data lines each corresponding to the data line 6a. To the gate of the TFT 30, a scanning line 3a is electrically coupled. To the scanning line 3a, scanning signals G1 through Gm are applied pulsatively and line-sequentially in this order at a predetermined timing.

The pixel electrode 19 is electrically coupled to the drain of the TFT 30. The TFT 30, which is a switching element, is switched on for a certain period, and thereby the pixel signals S1 through Sn are written in each pixel supplied from the data line 6a at a predetermined timing. The pixel signals S1 through Sn at a predetermined level written in the liquid crystal via the pixel electrode 19 are retained between the opposing electrode 20 and an opposing electrode 121 shown in FIG. 13 for a certain period. In order to prevent leak of the retained pixel signals S1 through Sn, a storage capacitor 60 is provided in parallel with a liquid crystal capacitor provided between the pixel electrode 19 and the opposing electrode 121. For example, the voltage of the pixel electrode 19 is retained by the storage capacitor 60 for a period of time several-hundred times longer than the time for which a source electrode is applied. Consequently, an electron retention property increases, thereby the liquid crystal device 100 with a high contrast ratio can be provided.

FIG. 15 is a partially enlarged sectional view of the liquid crystal device 100 including the TFT 30 of bottom-gate structure. On the substrate P made of glass included in the TFT array substrate 10, a gate wiring 61 is provided between banks B, B on the glass substrate P by the method for forming a circuit wiring according to the above-described embodiment.

On the gate wiring 61, the activation layer 63 that is a semiconductor layer made of an amorphous silicon (a-Si) layer is provided with a gate insulating film 62 made of SiNx therebetween. Part of the activation layer 63 placed face to face with this gate wiring area serves as a channel region. On the activation layer 63, the bonding layers 64a and 64b made of n+ a-Si layers, for example, are deposited in order to provide ohmic bonding. On the activation layer 63 in a central portion of the channel region, an insulating etch stop film 65 made of SiNx is provided so as to protect the channel. The gate insulating film 62, the activation layer 63, and the etch stop film 65 are patterned as shown, after CVD, by resist application, exposure to light and development, and photoetching.

Furthermore, the bonding layers 64a and 64b and the pixel electrode 19 made of ITO are also deposited and patterned as shown by photoetching. On the pixel electrode 19, the gate insulating film 62, and the etch stop film 65, banks 66, . . . are projectingly provided. Between the banks 66, . . . source line and drain lines are formed by discharging silver compound droplets with the above-described droplet discharge device IJ.

While the TFT 30 serves as a switching element to drive the liquid crystal display 100, it is also applicable for organic electroluminescent (EL) displays, for example. An EL display is an element in which a thin film containing fluorescent inorganic and organic compounds are sandwiched between a cathode and anode. By injecting electrons and holes into the thin film to recombine them and thus generate excitons, the element emits light by means of light emission (fluorescence/phosphorescence) as the excitons get deactivated. Among fluorescent materials used for an EL display element, materials exhibiting luminescent colors of red, green and blue, that is, materials for forming a light-emitting layer and a hole injection/electron transport layer are used as ink. The materials are patterned on a substrate including the TFT 30 so as to manufacture a light-emitting full color EL device. The scope of the electro-optic device according to the present embodiment of the invention includes this kind of organic EL device.

The electro-optic device according to the present embodiment of the invention is also applicable to plasma display panels and surface-conduction electron emitters that uses a phenomenon of emitting electrons by passing an electrical current through a small thin film on a substrate in parallel with the surface of the film.

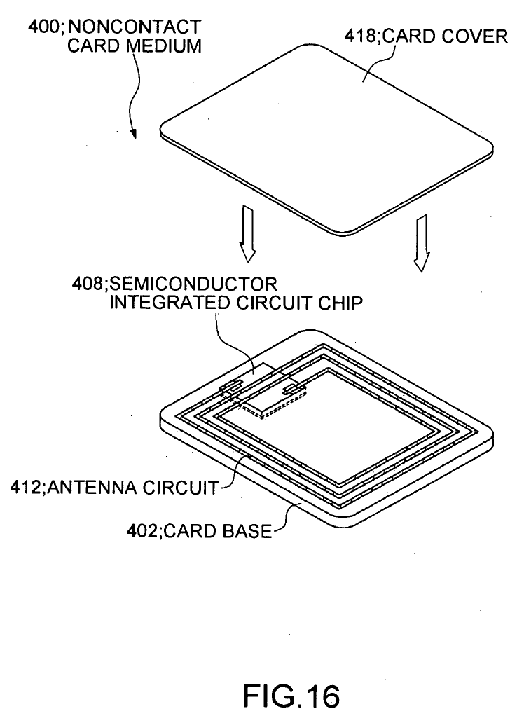

For another example other than forming a semiconductor device, a noncontact card medium will now be described. Referring to FIG. 16, this noncontact card medium (electronic apparatus) 400 includes a semiconductor integrated circuit chip 408 and an antenna circuit 412 housed in a case composed of a card base 402 and a card cover 418. The medium supplies electric power and/or communicates data with an outside transceiver (not shown) by using at least one of electromagnetic waves and electrostatic capacity coupling. The antenna circuit 412 is provided by the wiring pattern forming method of the above-described embodiment.

The third embodiment provides the following effects.

(1) By forming a concave portion having a sectional shape corresponding to a can be provided. In other words, provided with a circuit wiring made by a thin-film patter forming method that is capable of forming a thin film having a sufficient film thickness and sectional area for the thin film to provide its function, the liquid crystal display 100 includes the TFT 30 of high performance and thus offers advantages.

### Fourth Embodiment

An electronic apparatus according to a fourth embodiment of the invention will now described. This electronic apparatus that is a liquid crystal display according to the present embodiment is equipped with the liquid crystal display according to the third embodiment. The electronic apparatus according to the present embodiment will be illustrated in detail.

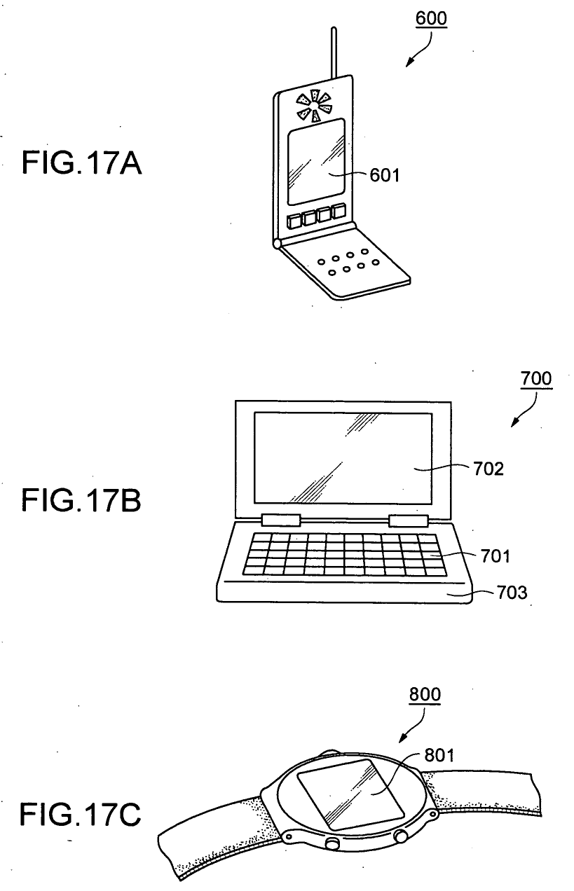

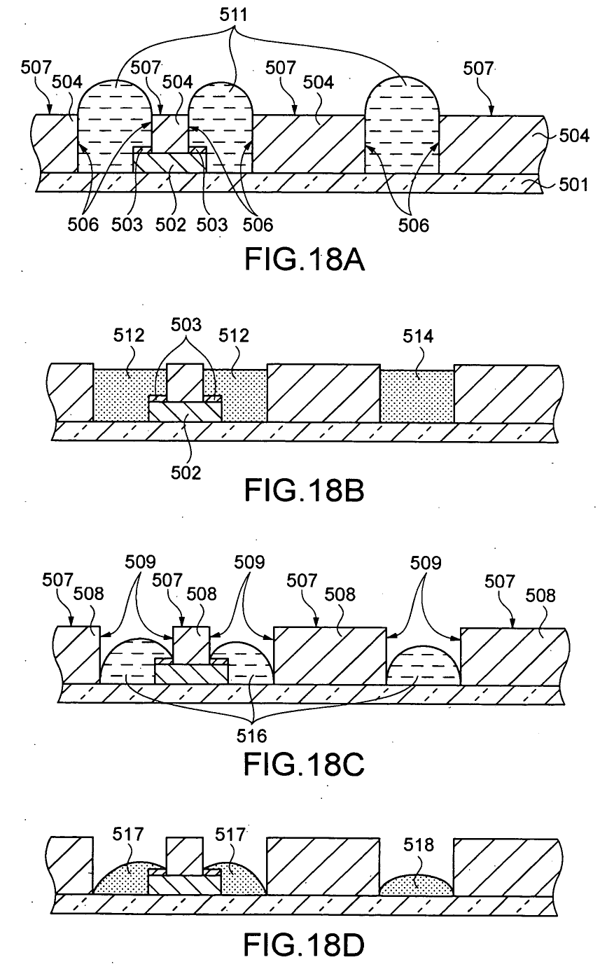

FIG. 17A is a perspective view illustrating a cellular phone that serves an example of this electronic apparatus. Referring to FIG. 17A, this cellular phone 600 includes a liquid crystal display unit 601 having the liquid crystal display 100 according to the above-described embodiment.

FIG. 17B is a perspective view illustrating a portable information processing device including a word processor and a personal computer. Referring to FIG. 17B, this information processing device 700 includes an input unit 701 such as a keyboard, an information processor body 703, and a liquid crystal display unit 702 having the liquid crystal display 100 according to the above-described embodiment.

FIG. 17C is a perspective view illustrating a wristwatch electronic apparatus. Referring to FIG. 17C, this wristwatch 800 includes a liquid crystal display unit 801 having the liquid crystal display 100 according to the above-described embodiment.

The electronic apparatuses shown in FIGS. 17A through 17C include the liquid crystal display according to the above-described embodiment. Provided with a circuit wiring made by a thin-film patter forming method that is capable of forming a thin film having a sufficient film thickness and sectional area for the thin film to provide its function, the display includes the TFT 30 of high performance. While the electronic apparatus according to the present embodiment is equipped with a liquid crystal device, the apparatus may be equipped with other electro-optic devices, such as an organic electroluminescent display and a plasma type display.

The fourth embodiment provides the following effects.

(1) Provided with a circuit wiring made by a thin-film patter forming method that is capable of forming a thin film having a sufficient film thickness and sectional area for the thin film to provide its function, the liquid crystal display 100 includes the TFT 30 of high performance and thus offers advantages. Thereby the cellular phone 600, information processing device 700, and the wristwatch 800 that offer high performance may be provided.

While the preferred embodiments of the present invention have been described referring to the accompanying drawings, it is understood that the present invention is not limited to them, and the following changes can be made.

First Modification

While a wiring pattern is provided by forming a conductive film in a groove between the banks B in the above-described embodiments, a thin film manufactured by this method is not limited to a wiring pattern made of a conductive film. For example, it is applicable to a color filter used to provide color display images with a liquid crystal display. Such a color filter is made by placing R, G, and B functional liquid (liquid material) droplets in a predetermined pattern on a substrate. In this case, banks corresponding to the shape of this color filter are formed on the substrate in the same manner as mentioned in the embodiments. By placing the functional liquid in a groove defined by the banks so as to form the color filter, a liquid crystal device including the color filter may be provided.

By placing the functional liquid in the groove whose side, which is also the side of one bank, is lyophilic, the functional liquid spreading to the edge of the bank clings to the bank, and thereby placing the functional liquid evenly inside the groove. Thus, by drying the functional liquid evenly inside the groove to provide the color filter, the color filter may be provided to an even thickness to the edge of the bank. Here, the color filter gives color to light by shielding a specific wavelength component of light passing through the filter. Since the amount of light the filter shields depends on its thickness, its thickness is an important factor that has an influence on the performance of the filter. Therefore, by forming the color filter to an even thickness, the color filter that offers high performance may be provided.

Second Modification

While a wiring pattern is provided by forming a conductive film in a groove between the banks B in the above-described embodiments, a thin film manufactured by this method is not limited to a wiring pattern made of a conductive film. The thin-film pattern forming method according to the embodiment of the invention is applicable to forming the insulating film 29 and the pixel electrode 19 described in the embodiment.

What is claimed is:

1. A thin-film pattern forming method that deposits a plurality of thin films on a substrate to form a thin-film pattern, comprising:
forming a second thin film on the substrate, the second thin film having an affinity for a functional liquid containing a thin-film material that makes up a first thin film;
providing lyophobic treatment that makes a surface of the second thin film repellent to the functional liquid;
forming a concave portion that defines a pattern shape of the first thin film by removing part of the second thin film;
discharging the functional liquid to the concave portion; and
forming the first thin film by drying the functional liquid discharged to the concave portion.

2. The thin-film pattern forming method according to claim 1, in forming the second thin film on the substrate, a material whose contact angle with respect to the functional liquid is 20 degrees or less being used as a material for forming the second thin film.

3. The thin-film pattern forming method according to claim 1, in providing lyophobic treatment, a contact angle of the surface of the second thin film with respect to the functional liquid being 90 degrees or more.

4. The thin-film pattern forming method according to claim 1, the first thin film being at least one of a source electrode and a source wiring of a semiconductor device.

5. The thin-film pattern forming method according to claim 1, the first thin film being a drain electrode of a thin-film transistor.

6. The thin-film pattern forming method according to claim 1, the first thin film being at least one of a gate wiring and a gate electrode of a semiconductor device.

7. A semiconductor device, comprising:
the first thin film formed by the thin-film pattern forming method according to claim 1.

8. An electro-optic device, comprising:
the semiconductor device according to claim 7.

9. An electronic apparatus, comprising:
the electro-optic device according to claim 8.
